(19) United States
(12) Patent Application Publication
(10) Pub. No.: US 2022/0352451 A1
(43) Pub. Date: Nov. 3, 2022

(54) THERMOELECTRIC STRUCTURE AND MANUFACTURING METHOD

(71) Applicant: TAIWAN SEMICONDUCTOR MANUFACTURING COMPANY, LTD., Hsinchu (TW)

(72) Inventors: Yu-Jie HUANG, Hsinchu (TW); Chung-Hui CHEN, Hsinchu (TW); Jui-Cheng HUANG, Hsinchu (TW); Tung-Tsun CHEN, Hsinchu (TW)

(21) Appl. No.: 17/857,467

(22) Filed: Jul. 5, 2022

Related U.S. Application Data
(62) Division of application No. 17/203,221, filed on Mar. 16, 2021.
(60) Provisional application No. 63/040,877, filed on Jun. 18, 2020.

(51) Int. Cl. H01L 35/04; H01L 27/16; H01L 35/30

(52) U.S. Cl. CPC H01L 35/04; H01L 27/16; H01L 35/30; H01L 35/10

(57) ABSTRACT

A method of manufacturing an integrated circuit structure includes forming active regions, forming source/drain regions, and forming conductive segments resulting in a thermoelectric structure including a p-type region positioned on a front side of the substrate, an n-type region positioned on the front side of the substrate, and a wire on the front side of the substrate configured to electrically couple the p-type region to the n-type region. The method includes forming a first via configured to thermally couple the p-type region to a first power structure on a back side of the substrate, forming a second via configured to thermally couple the n-type region to a second power structure on the back side of the substrate, and electrically coupling an energy device to each of the first and second power structures.

### PRIORITY CLAIM AND CROSS-REFERENCE

This application is a divisional of U.S. patent application Ser. No. 17/203,221, filed Mar. 16, 2021, which claims the benefit of U.S. Provisional Patent Application No. 63/040,877, filed Jun. 18, 2020, each of which is incorporated by reference herein in its entirety.

### BACKGROUND

High-density integrated circuits (ICs), for example central processing units (CPU) and memory, can generate heat which can cause issues such as abnormal functioning. Further, oxides surrounding the ICs and metal lines within the ICs are poor heat conductors, exacerbating the heat generation problem as the heat is trapped within the high-density ICs.

Electromigration (EM) is the transport of conductor material caused by the gradual movement of the conductor material due to momentum transfer between conducting electrons and diffusing metal atoms. EM is noticed in applications where high direct current densities are used, such as in microelectronics and related structures. As the structure size in electronics, such as ICs, decreases, the practical significance of EM often increases. EM is exacerbated by high current densities and Joule heating (i.e., heat that is generated whenever a current is passed through a conductive material) of the conductor, and can lead to eventual failure of electrical components (e.g., electrical shorts and opens created by conductor material migrating and creating an open circuit or touching another conductor and creating a short).

### BRIEF DESCRIPTION OF THE DRAWINGS

Aspects of the present disclosure are best understood from the following detailed description when read with the accompanying FIGS. It is noted that, in accordance with the standard practice in the industry, various features are not drawn to scale. In fact, the dimensions of the various features may be arbitrarily increased or reduced for clarity of discussion.

FIG. 1 is a cross-sectional diagram of a thermoelectric structure, in accordance with some embodiments.

FIG. 2 is a cross-sectional diagram of a thermoelectric structure, in accordance with some embodiments.

FIG. 3 is a cross-sectional diagram of a thermal structure, in accordance with some embodiments.

FIG. 4 is a cross-sectional diagram of a thermoelectric structure, in accordance with some embodiments.

FIGS. 5A-5C are cross-sectional diagrams of thermoelectric structures, in accordance with some embodiments.

FIGS. 6A and 6B are diagrams of thermoelectric structure arrays, in accordance with some embodiments.

FIG. 7 is a flow diagram of a method of cooling a circuit, in accordance with some embodiments.

FIG. 8 is a flowchart of a method of manufacturing an IC structure, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A thermoelectric structure includes a structure on a front side of a semiconductor substrate, e.g., a silicon substrate, thermally coupled to one or more back-side structures. In various active and/or passive structure embodiments, the front-side structure includes a thermocouple arrangement of n-type and p-type regions configured to cool adjacent high-density ICs or other heat sources by using the thermoelectric effect to transfer heat from the heat sources to the one or more back-side structures. In some embodiments, the thermoelectric structure includes one or more storage devices configured to store the heat energy released as electrical energy.

By being configured to use the thermoelectric effect for active and/or passive on-chip thermal cooling, the thermoelectric structure including one or more back-side structures is capable of realizing high-efficiency heat dissipation such that cooling of ICs is improved compared to approaches that do not include a thermoelectric structure. In embodiments in which energy generated by the heat dissipation is stored as electrical energy, overall power is saved compared to approaches that do not include a thermoelectric structure.

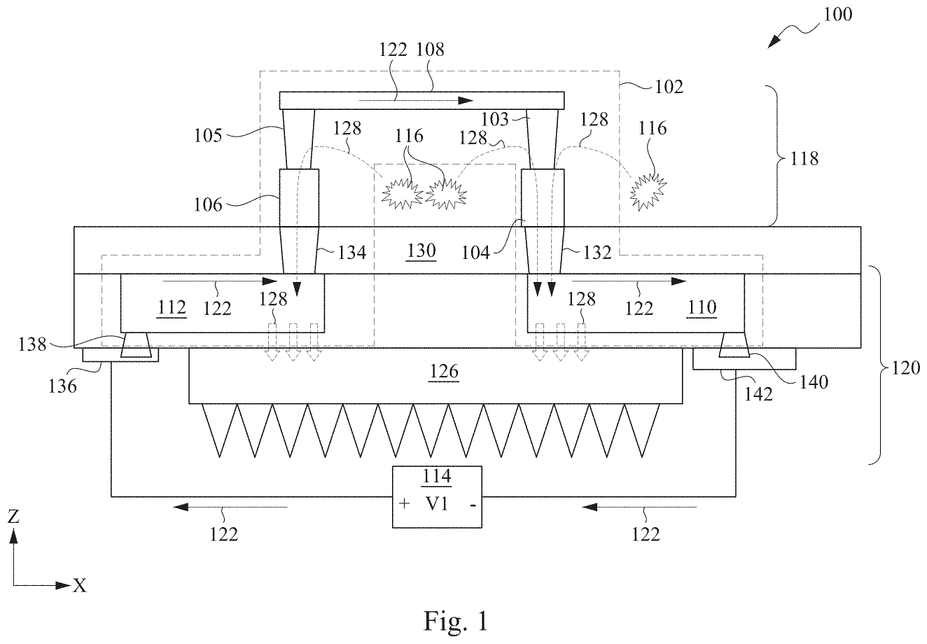

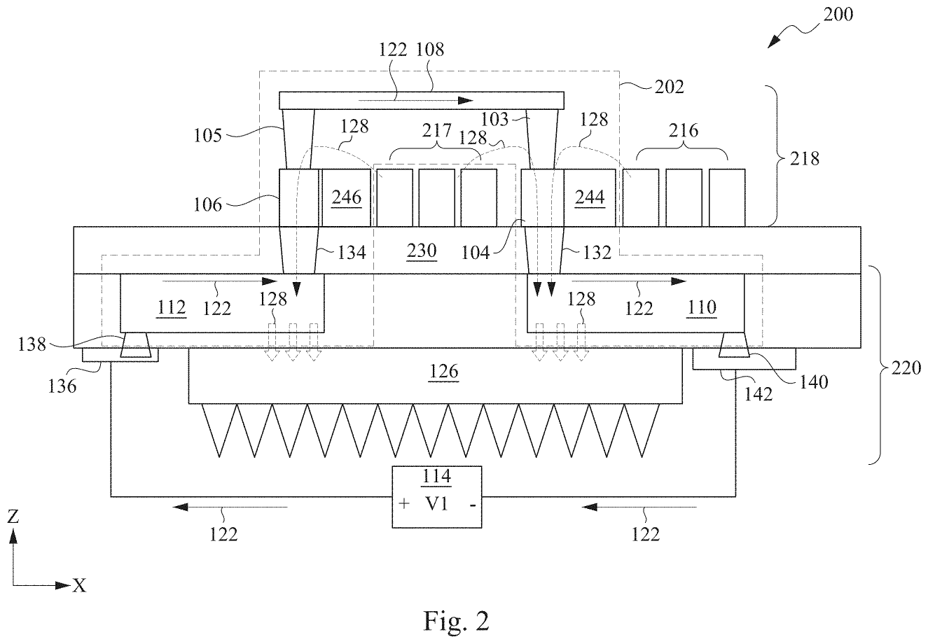

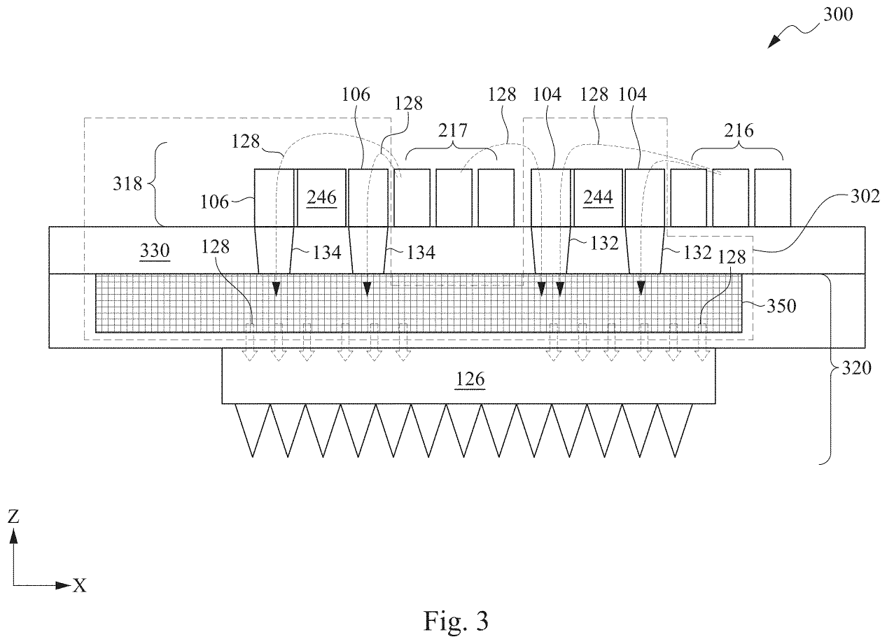

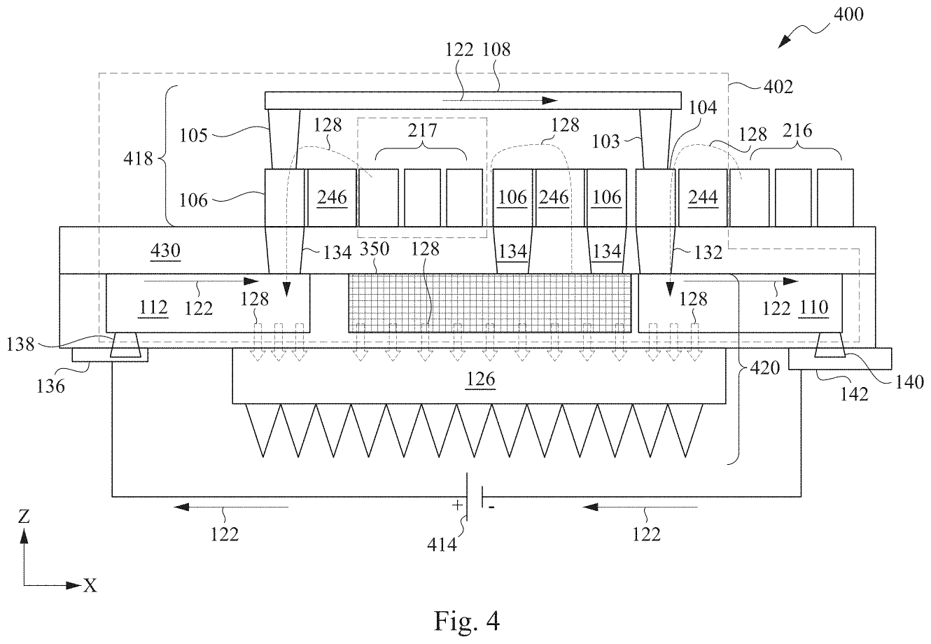

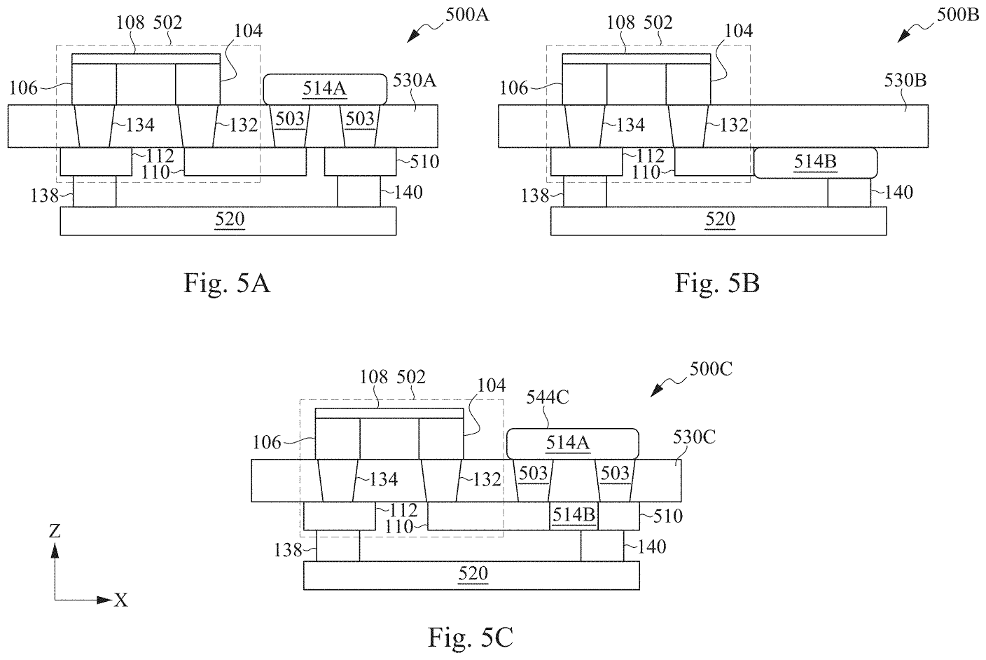

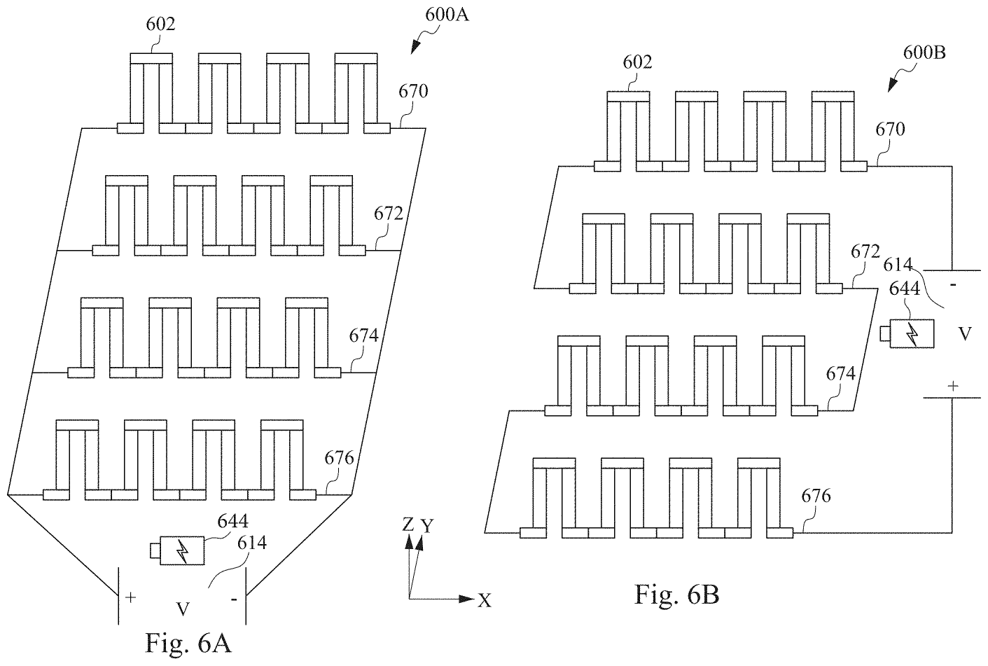

As discussed below, thermoelectric and thermal structure embodiments include active/passive structures including wide back-side metal segments depicted in FIGS. 1 and 2, a passive structure including a back-side mesh structure depicted in FIG. 3, a combination of active and passive structures including wide back-side metal segments and a back-side mesh structure depicted in FIG. 4, passive structures including energy storage devices depicted in FIGS. 5A-5C, and active/passive structure arrays depicted in FIGS. 6A and 6B.

FIG. 1 is a cross-sectional diagram of a circuit 100 including a thermoelectric structure 102, in accordance with some embodiments. In addition to thermoelectric structure 102, circuit 100 includes one or more heat sources 116 and an energy device 114. In addition to circuit 100, FIG. 1 depicts a heat sink 126, an X direction, and a Z direction perpendicular to the X direction. As discussed below, thermoelectric structure 102 is capable of operating as either an active or passive thermoelectric structure.

Circuit 100 is at least a portion of an IC including a portion of a substrate 130 which includes a front side 118 and a back side 120. A substrate, e.g., substrate 130, is a portion of a semiconductor wafer, e.g., a silicon wafer, suitable for forming one or more IC devices. A front side of a substrate, e.g., front side 118, corresponds to a surface of the substrate on which one or more IC devices are formed in a manufacturing process, and a back side, e.g., back side 120, corresponds to the opposing surface of the substrate. In some embodiments, a back side corresponds to a surface resulting from a thinning operation. In the embodiment depicted in FIG. 1, substrate 130 is depicted as oriented such that front side 118 is further along the positive Z direction than back side 120 solely for the purpose of illustration. In some embodiments, substrate 130 has an orientation other than that depicted in FIG. 1.

A heat source 116 is some or all of an IC, e.g., a high-density IC such as a CPU or memory circuit, that generates heat in operation, especially Joule heat, i.e., the heat generated whenever a current passes through a conductive material. Heat sources 116 are electrically isolated from thermoelectric structure 102 and sufficiently close to one or more components of thermoelectric structure 102 such that heat is capable of being conducted from heat sources 116 to the one or more components of thermoelectric structure 102. Because heat sources 116 are electrically isolated from thermoelectric structure 102, each of heat sources 116 or thermoelectric structure 102 is capable of operation independent of the other of heat sources 116 or thermoelectric structure 102.

In various embodiments, a heat source includes one or more passive devices, e.g., a resistive or inductive device, and/or an active device, e.g., one or both of a p-type metal-oxide-semiconductor (PMOS) active device 216 or an n-type metal-oxide-semiconductor (NMOS) active device 217 discussed below with respect to FIG. 2.

Energy device 114 is an electrical, electromechanical, and/or electrochemical physical assembly configured to, in operation, either provide or receive a voltage V1. In some embodiments, energy device 114 is external to substrate 130. In some embodiments, energy device 114 includes an energy source, e.g., a power supply or a battery, configured to provide voltage V1 such that thermoelectric structure 102 operates as an active device, as discussed below. In some embodiments energy device 114 includes an energy storage or dissipation device, e.g., a capacitive device, battery, or conductive element, configured to receive voltage V1 such that thermoelectric structure 102 operates as a passive device, as discussed below.

A heat sink, e.g., heat sink 126, is a mechanical structure configured as a passive heat exchanger whereby heat received from an adjacent structure, e.g., power structure 110 or 112, is transferred to a fluid medium, e.g., air or a liquid coolant, and dissipated away from the adjacent structure, thereby allowing regulation of the structure's temperature. In some embodiments, a heat sink is designed to enhance its surface area in contact with the fluid medium, e.g., by including fins or other protrusions that provide a large surface area over which exchange of heat occurs. In various embodiments, a heat sink includes one or more thermally conductive materials, e.g., aluminum, copper, or another material suitable for providing high thermal conductivity.

Thermoelectric structure 102 includes some or all of the portion of substrate 130 included in circuit 100; a p-type region 104, an n-type region 106, vias 103 and 105, and a wire 108 positioned on front side 118; vias 132 and 134 positioned in substrate 130; and power structures 110 and 112, vias 138 and 140, and pads 136 and 142 positioned on back side 120.

Wire 108 is electrically connected to pad 142 through via 103, p-type region 104, via 132, power structure 110, and via 140. Wire 108 is also electrically connected to pad 136 through via 105, n-type region 106, via 134, power structure 112, and via 138. In some embodiments, thermoelectric structure 102 does not include via 140, pad 142, via 138, and pad 136, and wire 108 is electrically connected to power structures 110 and 112 accordingly. In some embodiments, via 140, pad 142, via 138, and pad 136 are included in a circuit, e.g., circuit 100, that is external to and/or includes thermoelectric structure 102.

Each of FIGS. 1-6B is simplified for the purpose of illustration such that an uppermost front-side feature, e.g., wire 108, is depicted as being electrically connected to a lowermost back-side feature, e.g., pad 142 or 136, through features in direct contact with adjacent features. In various embodiments, a thermoelectric structure, e.g., thermoelectric structure 102, includes one or more features in addition to those depicted in FIGS. 1-6B through which the uppermost front-side feature is electrically connected to the lowermost back-side feature. For example, in some embodiments, thermoelectric structure 102 includes one or more silicide layers (not shown) positioned between p-type region 104 and one or both of vias 103 or 132 and/or positioned between n-type region 106 and one or both of vias 105 or 134.

A wire, e.g., wire 108, is a conductive segment extending along the X direction and overlying each of vias 103 and 105, and is thereby configured to provide a low resistance path between vias 103 and 105. A conductive segment is a volume configured to provide a low electrical and/or thermal resistance path by including one or more conductive materials, e.g., a metal such as copper, aluminum, tungsten, or titanium, polysilicon, or another material capable of providing a low resistance path. Additionally or alternatively, the one or more conductive materials include a material with high thermoelectric properties, such as bismuth telluride, lead telluride, silicon-germanium, sodium cobaltate, tin selenide, and the like. In some embodiments, a conductive segment includes one or more conductive materials configured as one or more barrier layers.

A via, e.g., a via 103, 105, 132, or 134, is a conductive segment extending in the Z direction and configured to provide a low electrical and/or thermal resistance path between an overlying feature, e.g., wire 108, p-type region 104, or n-type region 106, and an underlying feature, e.g., p-type region 104, n-type region 106, or one of power structures 110 or 112. In some embodiments, a via, e.g., via 132 or 134, extends from the front side of a substrate to the back side of the substrate. In some embodiments, a via extending from the front side of a substrate to the back side of the substrate, i.e., through the substrate, is referred to as a back-side via or a through silicon via.

A region, e.g., p-type region 104 or n-type region 106, is a volume in an active area (not shown) of a substrate, e.g., substrate 130, including one or more semiconductor materials and/or one or more dopants configured to provide a predetermined charge carrier concentration. In some embodiments, the active area is electrically isolated from other elements in the substrate by one or more isolation structures (not shown), e.g., one or more shallow trench isolation (STI) structures. In some embodiments, the active area is positioned in a well (not shown), e.g., is a p-type active area positioned in an n-well.

In various embodiments, the one or more semiconductor materials include silicon (Si), indium phosphide (InP), germanium (Ge), gallium arsenide (GaAs), silicon germanium (SiGe), indium arsenide (InAs), silicon carbide (SiC), or another material suitable for providing the predetermined charge carrier concentration. In various embodiments, the one or more dopants include one or more donor dopants, e.g., phosphorous (P) or arsenic (As), corresponding to an n-type region, e.g., n-type region 106, or one or more acceptor dopants, e.g., boron (B) or aluminum (Al), corresponding to a p-type region, e.g., p-type region 104.

In various embodiments, a p-type or n-type region includes the one or more semiconductor materials the same or different from one or more semiconductor materials of the substrate. In some embodiments, a p-type or n-type region includes one or more epitaxial layers of the one or more semiconductor materials. In various embodiments, a p-type or n-type region corresponds to a source/drain (S/D) region of a planar field-effect transistor (FET), a fin field-effect transistor (FinFET), a gate-all-around (GAA) transistor, a complementary field-effect transistor (CFET), or the like.

A power structure, e.g., power structure 110 or 112, is a conductive segment included in a back-side power distribution structure. A power distribution structure, also referred to as a power distribution network in some embodiments, includes a plurality of conductive segments supported and electrically separated by a plurality of insulation layers and arranged in accordance with power delivery requirements, e.g., of one or more IC devices of the front side of the substrate. In various embodiments, a power distribution structure includes one or a combination of a power rail, a super power rail, a buried power rail, conductive segments arranged in a grid or mesh structure, or another arrangement suitable for distributing power to one or more IC devices. In some embodiments, one or both of power structure 110 or 112 is referred to as a power rail or super power rail.

A pad, e.g., pad 136 or 142, is a conductive segment configured to provide an electrical interface between one or more conductive elements on the substrate and one or more circuits, e.g., energy device 114 in some embodiments, external to the substrate.

By the configuration discussed above, thermoelectric structure 102 includes p-type region 104 and n-type region 106 electrically connected to each other through wire 108, and to power structures 110 and 112 through vias 132 and 134, respectively. In some embodiments, thermoelectric structure 102 includes p-type region 104 and n-type region 106 further electrically connected to pads 142 and 136 through vias 140 and 138, respectively.

By including p-type region 104 and n-type region 106 electrically connected to each other and to respective back-side conductive segments, thermoelectric structure 102 includes a thermocouple arrangement of p-type region 104 and n-type region 106 configured to, in operation, cool heat sources 116 adjacent to p-type region 104 and n-type region 106 by using the thermoelectric effect to transfer heat from heat sources 116 to the respective back-side conductive segments as discussed below. In FIGS. 1-4, heat transfer corresponding to a thermocouple structure, e.g., thermoelectric structure 102, is indicated by heat transfer 128 arrows. In some embodiments, a thermoelectric structure, e.g., thermoelectric structure 102, is referred to as a thermoelectric cooler structure.

In some embodiments, energy device 114 is electrically coupled to each of pads 142 and 136 or each of power structures 110 and 112 and includes an energy source, and thermoelectric structure 102 is thereby configured as an active thermoelectric structure. In some embodiments, energy device 114 is electrically coupled to each of pads 142 and 136 or each of power structures 110 and 112 and includes an energy storage device, and thermoelectric structure 102 is thereby configured as a passive thermoelectric structure.

In some embodiments, each of power structures 110 and 112 is electrically isolated from heat sink 126 and positioned sufficiently close to heat sink 126 such that heat is capable of being conducted from power structures 110 and 112 to heat sink 126. Because each of power structures 110 and 112 is electrically isolated from heat sink 126, thermoelectric structure 102 is capable of operation independent of the presence of heat sink 126. In some embodiments, circuit 100 does not include heat sink 126, and thermoelectric structure 102 is otherwise capable of conducting heat from power structures 110 and 112, e.g., directly to air or to another electrically isolated portion of a back-side power structure, e.g., a mesh structure 350 discussed below with respect to FIG. 3.

In operation, a thermoelectric structure, e.g., thermoelectric structure 102, generates a voltage when there is a temperature difference across the thermoelectric structure, i.e., a temperature difference between front side 118 and back side 120. In the presence of a current path between power structures 110 and 112, the voltage generated based on front side 118 having a temperature greater than that of back side 120 voltage induces a current 122 in which each of positive charge carriers in p-type region 104 and negative charge carriers in n-type region 106 moves in the negative Z direction. The charge carrier movement corresponding to current 122 acts to transfer heat from front side 118 to back side 120 (depicted as heat transfer 128), thereby cooling heat sources 116 adjacent to p-type region 104 and n-type region 106. In some embodiments, heat transfer 128 includes heat transfer to a heat sink, e.g., heat sink 126.

In embodiments in which energy device 114 includes an energy source, applied voltage V1 thereby causes current 122 to flow such that heat transfer 128 is increased above a level that would otherwise occur in the absence of applied voltage V1, such that cooling of heat sources 116 is increased.

In embodiments in which energy device 114 includes an energy storage device, heat generated by heat sources 116 causes current 122 to flow such that voltage V1 received by energy device 114 corresponds to electrical energy capable of increasing a stored energy level of energy device 114 compared to a stored energy level in the absence of current 122.

By the configuration discussed above, thermoelectric structure 102 is capable of using the thermoelectric effect for active and/or passive on-chip thermal cooling whereby back-side power structures 110 and 112 realize high-efficiency heat dissipation from front-side heat sources 116 such that cooling of front-side heat sources 116 is improved compared to approaches that do not include a thermoelectric structure. In embodiments in which energy generated by the heat dissipation is stored as electrical energy, overall power of circuit 100 is saved compared to approaches that do not include a thermoelectric structure.

FIG. 2 is a cross-sectional diagram of a circuit 200 including a thermoelectric structure 202, in accordance with some embodiments. In addition to thermoelectric structure 202, circuit 200 includes energy device 114, and in addition to circuit 200, FIG. 2 depicts heat sink 126 and the X and Z directions, each discussed above with respect to FIG. 1. Circuit 200 is an IC including a portion of a substrate 230 which includes a front side 218 and a back side 220, PMOS active device 216, and NMOS active device 217.

Thermoelectric structure 202 includes some or all of the portion of substrate 230 included in circuit 200; wire 108, p-type region 104, n-type region 106, and vias 103 and 105 positioned on front side 218; vias 132 and 134 positioned in substrate 230; and power structures 110 and 112, vias 138 and 140, and pads 136 and 142 positioned on back side 220, configured as discussed above with respect to thermoelectric structure 102 and FIG. 1. Thermoelectric structure 202 also includes a PMOS dummy device 244 adjacent to p-type region 104 and an NMOS dummy device 246 adjacent to n-type region 106.

A PMOS device, e.g., PMOS active device 216 or PMOS dummy device 244, includes some or all of a transistor device including a p-type active area, and an NMOS device, e.g., NMOS active device 217 or NMOS dummy device 246, includes some or all of a transistor device including an n-type active area. In some embodiments, a PMOS device includes a plurality of transistor devices, each including a p-type active area, and/or an NMOS device includes a plurality of transistor devices, each including an n-type active area.

PMOS active device 216 and NMOS active device 217 are components of one or more ICs usable as one or more heat sources 116 discussed above with respect to FIG. 1. In various embodiments, PMOS active device 216 and NMOS active device 217 are components of a same or separate ICs.

PMOS dummy device 244 is electrically and thermally coupled to p-type region 104, and thermally coupled to and electrically isolated from PMOS active device 216. NMOS dummy device 246 is electrically and thermally coupled to n-type region 106, and thermally coupled to and electrically isolated from NMOS active device 217.

In the embodiment depicted in FIG. 2, NMOS dummy device 246 and NMOS active device 217 are positioned between p-type region 104 and n-type region 106 such that circuit 200 is configured to transfer heat from NMOS active device 217 to thermoelectric structure 202. In various embodiments, circuit 200 is otherwise configured to transfer heat from NMOS active device 217 to thermoelectric structure 202, e.g., by including n-type region 106 positioned between p-type region 104 and the combination of NMOS dummy device 246 and NMOS active device 217.

In the embodiment depicted in FIG. 2, p-type region 104 is positioned between n-type region 106 and the combination of PMOS dummy device 244 and PMOS active device 216 such that circuit 200 is configured to transfer heat from PMOS active device 216 to thermoelectric structure 202. In various embodiments, circuit 200 is otherwise configured to transfer heat from PMOS active device 216 to thermoelectric structure 202, e.g., by including PMOS dummy device 244 and PMOS active device 216 positioned between p-type region 104 and n-type region 106.

In some embodiments, circuit 200 includes both the combination of PMOS dummy device 244 and PMOS active device 216 and the combination of NMOS dummy device 246 and NMOS active device 217 positioned between p-type region 104 and n-type region 106. In some embodiments, circuit 200 includes more than one instance of PMOS dummy device 244 electrically and thermally coupled to p-type region 104 and/or more than one instance of NMOS dummy device 246 electrically and thermally coupled to n-type region 106.

By the configuration discussed above, circuit 200 including thermoelectric structure 202 has the thermoelectric properties discussed above with respect to circuit 100. Thermoelectric structure 202 is thereby capable of being configured as either an active or passive thermoelectric structure having the benefits discussed above with respect to circuit 100 including thermoelectric structure 102.

FIG. 3 is a cross-sectional diagram of a circuit 300 including a thermal structure 302, in accordance with some embodiments. In addition to circuit 300, FIG. 3 depicts heat sink 126 and the X and Z directions, each discussed above with respect to FIG. 1. Circuit 300 is an IC including PMOS active device 216 and NMOS active device 217, discussed above with respect to FIG. 2, and a portion of a substrate 330 which includes a front side 318 and a back side 320.

Thermal structure 302 includes some or all of the portion of substrate 330 included in circuit 300; PMOS dummy device 244 positioned between two instances of p-type region 104, and NMOS dummy device 246 positioned between two instances of n-type region 106 on front side 318; two instances each of vias 132 and 134 positioned in substrate 330; and mesh structure 350 positioned on back side 320.

Mesh structure 350 is a portion of a back-side power structure including conductive segments having a mesh arrangement, and is thermally coupled to heat sink 126. In various embodiments, mesh structure 350 and heat sink 126 are either electrically coupled to each other or electrically isolated from each other.

Each instance of p-type region 104 is thermally coupled to mesh structure 350 through a corresponding instance of via 132, and each instance of n-type region 106 is thermally coupled to mesh structure 350 through a corresponding instance of via 134. In various embodiments, one or more instances of p-type region 104 and/or one or more instances of n-type region 106 are electrically coupled to mesh structure 350 through one or more corresponding instances of vias 132 and/or 134.

The two instances of p-type region 104 are thermally and electrically coupled to each other through PMOS dummy device 244, and at least one instance of p-type region 104 is adjacent to PMOS active device 216 and thereby thermally coupled to and electrically isolated from PMOS active device 216.

The two instances of n-type region 106 are thermally and electrically coupled to each other through NMOS dummy device 246, and at least one instance of n-type region 106 is adjacent to NMOS active device 217 and thereby thermally coupled to and electrically isolated from NMOS active device 217.

In the embodiment depicted in FIG. 3, circuit 300 including thermal structure 302 is thereby configured to, in operation, transfer heat from PMOS active device 216 to mesh structure 350 through the corresponding pair of p-type regions 104 and vias 132, and from NMOS active device 217 to mesh structure 350 through the corresponding pair of n-type regions 106 and vias 134. In various embodiments, circuit 300 including thermal structure 302 is otherwise configured to transfer heat from one or both of PMOS active device 216 or NMOS active device 217 to mesh structure 350, e.g., by thermal structure 302 including a single instance or more than two instances of p-type regions 104 and vias 132 and/or a single instance or more than two instances of n-type regions 106 and vias 134.

In various embodiments, circuit 300 includes arrangements of PMOS active device 216 and/or NMOS active device 217 other than that depicted in FIG. 3, e.g., is free from including one of PMOS active device 216 or NMOS active device 217 or includes two or more of PMOS active device 216 and/or NMOS active device 217, and is thereby configured to, in operation, transfer heat from the one or more of PMOS active device 216 and/or NMOS active device 217 to mesh structure 350.

By the configuration discussed above, thermal structure 302 is a passive thermal structure capable of providing passive on-chip thermal cooling whereby back-side mesh structure 350 and, if present, heat sink 126 realize high-efficiency heat dissipation from the one or more of PMOS active device 216 and/or NMOS active device 217 such that cooling of the one or more of PMOS active device 216 and/or NMOS active device 217 is improved compared to approaches that do not include a thermal structure.

FIG. 4 is a cross-sectional diagram of a circuit 400 including a thermoelectric structure 402, in accordance with some embodiments. In addition to thermoelectric structure 402, circuit 400 includes an energy source 414, and in addition to circuit 400, FIG. 4 depicts heat sink 126 and the X and Z directions, each discussed above with respect to FIG. 1. Circuit 400 is an IC including a portion of a substrate 430 which includes a front side 418 and a back side 420, and PMOS active device 216 and NMOS active device 217 discussed above with respect to FIG. 2.

Thermoelectric structure 402 includes some or all of the portion of substrate 430 included in circuit 400; wire 108, p-type region 104, PMOS dummy device 244, a first instance of n-type region 106, a first instance of NMOS dummy device 246, and vias 103 and 105 positioned on front side 418; via 132 and a first instance of via 134 positioned in substrate 430; and power structures 110 and 112, vias 138 and 140, and pads 136 and 142 positioned on back side 420, configured as discussed above with respect to thermoelectric structure 202 and FIG. 2. Thermoelectric structure 402 also includes a second instance of NMOS dummy device 246 positioned between second and third instances of n-type region 106 on front side 418; second and third instances of via 134 positioned in substrate 430; and mesh structure 350 positioned on back side 420, configured as discussed above with respect to thermal structure 302 and FIG. 3.

Thermoelectric structure 402 is thereby configured as a combination of a first portion equivalent to thermoelectric structure 202, capable of being configured as either one of an active or passive thermoelectric structure, and a second portion equivalent to passive thermal structure 302.

In the embodiment depicted in FIG. 4, energy source 414 is electrically coupled to each of pads 142 and 136 (or each of power structures 110 and 112 in some embodiments), and the first portion of thermoelectric structure 402 is thereby configured as an active thermoelectric structure. In some embodiments, an energy storage device (not shown) is electrically coupled to each of pads 142 and 136 or each of power structures 110 and 112, and the first portion of thermoelectric structure 402 is thereby configured as a passive thermoelectric structure.

In the embodiment depicted in FIG. 4, circuit 400 includes PMOS active device 216 thermally coupled to and electrically isolated from PMOS dummy device 244, and NMOS active device 217 thermally coupled to and electrically isolated from the first instance of NMOS dummy device 246, and is thereby configured to, in operation, transfer heat from each of PMOS active device 216 and NMOS active device 217 to the first portion of thermoelectric structure 402. In various embodiments, circuit 400 and the first portion of thermoelectric structure 402 are otherwise configured to, as discussed above with respect to FIG. 2, transfer heat from one or more instances of PMOS active device 216 and/or NMOS active device 217 to the first portion of thermoelectric structure 402.

In the embodiment depicted in FIG. 4, circuit 400 includes NMOS active device 217 thermally coupled to and electrically isolated from the second instance of n-type region 106, and is thereby configured to, in operation, transfer heat from NMOS active device 217 to the second portion of thermoelectric structure 402. In various embodiments, circuit 400 and the second portion of thermoelectric structure 402 are otherwise configured to, as discussed above with respect to FIG. 3, transfer heat from one or more instances of PMOS active device 216 or NMOS active device 217 to the second portion of thermoelectric structure 402.

By the configuration discussed above, circuit 400 including thermoelectric structure 402 has the thermoelectric properties discussed above with respect to circuit 200 and the thermal properties discussed above with respect to FIG. 3. Thermoelectric structure 402 is thereby configured as a first portion capable of being configured as an active or passive thermoelectric structure combined with a second, passive thermal structure portion, the combination having the benefits discussed above with respect to each of circuit 200 including thermoelectric structure 202 and circuit 300 including thermal structure 302.

FIGS. 5A-5C are cross-sectional diagrams of circuits 500A-500C, each including a thermoelectric structure 502, in accordance with some embodiments. In addition to thermoelectric structure 502, circuits 500A-500C include a conductive segment 520 and one or both of capacitive devices 514A-514B. In addition to circuits 500A-500C, FIGS. 5A-5C depict the X and Z directions discussed above with respect to FIG. 1. Circuits 500A-500C are ICs including corresponding portions of substrates 530A-530C on which capacitive devices 514A and 514B are positioned as discussed below.

Thermoelectric structure 502 includes some or all of the corresponding portion of substrate 530A-530C included in circuit 500A-500C; wire 108, p-type region 104, n-type region 106, vias 132 and 134, and power structures 110 and 112, and is thereby usable as either of thermoelectric structures 102 or 202 discussed above with respect to FIGS. 1 and 2. The embodiments depicted in FIGS. 5A-5C are simplified for the purpose of illustration. In various embodiments, thermoelectric structure 502 includes one or more features in addition to those depicted in FIGS. 5A-5C, e.g., via 103, via 105, PMOS dummy device 244, and/or NMOS dummy device 246 discussed above with respect to FIGS. 1 and 2.

As depicted in FIGS. 5A-5C, each of respective circuits 500A-500C includes vias 138 and 140, discussed above with respect to FIG. 1, electrically coupled to each other through conductive segment 520. Conductive segment 520 is a portion of a back-side power structure, e.g., positioned in a layer adjacent to vias 138 and 140.

As depicted in FIGS. 5A and 5C, each of circuits 500A and 500C includes a conductive segment 510 electrically coupled to via 140, a via 503 electrically coupled to conductive segment 510, a via 503 electrically coupled to power structure 110, and capacitive device 514A positioned on a front side (not labeled) of the corresponding substrate 530A or 530C, and electrically coupled to each of vias 503.

Vias 503 are positioned in substrate 530A or 530C and are analogous to vias 132 and 134 discussed above with respect to FIG. 1, and conductive segment 510 is a portion of a back-side power structure. In the embodiments depicted in FIGS. 5A and 5C, conductive segment 510 is positioned in a same layer as that of power structures 110 and 112. In some embodiments, conductive segment 510 is referred to as a power rail or super power rail. In some embodiments, conductive segment 510 is positioned in a layer other than that of power structures 110 and 112.

In the embodiments depicted in FIGS. 5A and 5C, power structure 110 is directly connected to via 503, and via 503 is directly connected to capacitive device 514A, power structure 110 thereby being electrically coupled to capacitive device 514A. Conductive segment 520 is directly connected to vias 138 and 140, conductive segment 510 is directly connected to vias 140 and 503, and via 503 is directly connected to capacitive device 514A, power structure 112 thereby being electrically coupled to capacitive device 514A. In various embodiments, circuit 500A and/or 500C includes one or more features (not shown) in addition to or instead of via 138, via 140, conductive segment 520, conductive segment 510, or vias 503, and is otherwise configured such that power structures 110 and 112 are electrically coupled to capacitive device 514A.

A capacitive device, e.g., capacitive device 514A, is an IC device including one or more IC structures configured to provide a predetermined capacitance between two terminals, e.g., terminals coupled to vias 503. In various embodiments, a capacitive device includes one or more of a plate capacitor, e.g., a metal-insulator-metal (MIM) capacitor, a capacitor-configured MOS device, or an adjustable capacitor, e.g., a MOSCAP, a capacitor network, or another IC structure capable of providing the predetermined capacitance. A capacitive device is thereby configured to be usable as an energy storage device, e.g., an energy storage embodiment of energy device 114 discussed above with respect to FIGS. 1-4.

In the embodiments depicted in FIGS. 5A and 5C, each of circuits 500A and 500C includes a single instance of capacitive device 514A positioned on the front side of the corresponding substrate 530A or 530C. In some embodiments, at least one of circuits 500A or 500C includes two or more instances of capacitive device 514A (not shown) arranged in parallel on the front side of the corresponding substrate 530A or 530C.

By the configuration discussed above, each of circuits 500A and 500C includes thermoelectric structure 502 coupled to capacitive device 514A through power structures 110 and 112 such that thermoelectric structure 502 is configured as a passive thermoelectric structure capable of realizing the benefits discussed above with respect to circuits 100 and 200. In some embodiments, thermoelectric structure 502 is considered to include one or more of via 138, via 140, conductive segment 520, conductive segment 510, vias 503, or capacitive device 514A and is thereby configured as a passive thermoelectric structure capable of realizing the benefits discussed above with respect to circuits 100 and 200.

As depicted in FIGS. 5B and 5C, each of circuits 500B and 500C includes capacitive device 514B positioned on a back side (not labeled) of the corresponding substrate 530B or 530C, and electrically coupled to power structure 110 and via 140.

In the embodiments depicted in FIGS. 5B and 5C, power structure 110 is directly connected to capacitive device 514B, power structure 110 thereby being electrically coupled to capacitive device 514B. In the embodiment depicted in FIG. 5B, conductive segment 520 is directly connected to vias 138 and 140, and via 140 is directly connected to capacitive device 514B, power structure 112 thereby being electrically coupled to capacitive device 514B. In the embodiment depicted in FIG. 5C, conductive segment 520 is directly connected to vias 138 and 140, via 140 is directly connected to conductive segment 510, and conductive segment 510 is directly connected to capacitive device 514B, power structure 112 thereby being electrically coupled to capacitive device 514B. In various embodiments, circuit 500B and/or 500C includes one or more features (not shown) in addition to or instead of via 138, via 140, conductive segment 520, or conductive segment 510, and is otherwise configured such that power structures 110 and 112 are electrically coupled to capacitive device 514B.

In the embodiments depicted in FIGS. 5B and 5C, each of circuits 500B and 500C includes a single instance of capacitive device 514B positioned on the back side of the corresponding substrate 530B or 530C. In some embodiments, at least one of circuits 500B or 500C includes two or more instances of capacitive device 514B (not shown) arranged in parallel on the back side of the corresponding substrate 530B or 530C.

By the configuration discussed above, each of circuits 500B and 500C includes thermoelectric structure 502 coupled to capacitive device 514B through power structures 110 and 112 such that thermoelectric structure 502 is configured as a passive thermoelectric structure capable of realizing the benefits discussed above with respect to circuits 100 and 200. In some embodiments, thermoelectric structure 502 is considered to include one or more of all of via 138, via 140, conductive segment 520, conductive segment 510, or capacitive device 514B and is thereby configured as a passive thermoelectric structure capable of realizing the benefits discussed above with respect to circuits 100 and 200.

By the configuration discussed above, circuit 500C includes capacitive devices 514A and 514B arranged in parallel such that, compared to each of circuits 500A and 500B, circuit 500C is capable of realizing the benefits discussed above with respect to circuits 100 and 200 based on a sum of predetermined capacitances of at least two capacitive devices.

FIGS. 6A and 6B are diagrams of respective thermoelectric structure arrays 600A and 600B, each including an array of thermoelectric structures 602, in accordance with some embodiments. In addition to thermoelectric structures 602, each of arrays 600A and 600B includes either an energy source 614 or an energy storage device 644. Energy source 614 corresponds to an energy source embodiment of energy device 114, and energy storage device 644 corresponds to an energy storage embodiment of energy device 114 discussed above with respect to FIGS. 1-4. In addition to arrays 600A and 600B, FIGS. 6A and 6B depict the X and Z directions discussed above with respect to FIG. 1, and a Y direction perpendicular to each of the X and Z directions.

Each of arrays 600A and 600B includes multiple thermoelectric structures 602 distributed across an X-Y plane corresponding to front and back surfaces of a substrate (not shown), e.g., one of substrates 130-530C discussed above with respect to FIGS. 1-5C. In the non-limiting examples depicted in FIGS. 6A and 6B, thermoelectric structures 602 are arranged in rows 670, 672, 674, and 676 (670-676) extending in the X direction and offset from each other along the Y direction. Each row 670-676 includes two or more instances of thermoelectric structure 602 coupled in series. In some embodiments, a p-type region of one instance of thermoelectric structure 602 is coupled to an n-type region of another instance of thermoelectric structure 602.

Each instance of thermoelectric structure 602 is one of thermoelectric structure 102 discussed above with respect to FIG. 1, thermoelectric structure 202 discussed above with respect to FIG. 2, thermoelectric structure 402 discussed above with respect to FIG. 4, or thermoelectric structure 502 discussed above with respect to FIGS. 5A-5C. In various embodiments, each instance of thermoelectric structure 602 is a same one of thermoelectric structures 102, 202, 402, or 502, or the instances of thermoelectric structure 602 include more than one of thermoelectric structures 102, 202, 402, or 502.

Array 600A includes rows 670-676 arranged in parallel such that each row 670-676 is coupled to energy source 614 or energy storage device 644. Array 600B includes rows 670-676 arranged in series such that an entirety of rows 670-676 is coupled to energy source 614 or energy storage device 644.

In the embodiments depicted in FIGS. 6A and 6B, each of arrays 600A and 600B includes a total of four rows 670-676, each row including a total of four instances of thermoelectric structure 602. In various embodiments, at least one of arrays 600A or 600B includes a total of fewer or greater than four rows of instances of thermoelectric structure 602. In various embodiments, at least one of arrays 600A or 600B includes each row, e.g., rows 670-676, including a total of fewer or greater than four instances of thermoelectric structure 602.

The embodiments depicted in FIGS. 6A and 6B are simplified for the purpose of illustration. In various embodiments, at least one of array 600A or 600B includes one or more features in addition to those depicted in FIGS. 6A and 6B, e.g., one or more conductive segments and/or vias, whereby arrays 600A and 600B are configured as discussed above.

By the configurations discussed above, each of arrays 600A and 600B includes two or more instances of thermoelectric structure 602 capable of realizing the benefits discussed above with respect to thermoelectric structures 102, 202, 402, and 502. Compared to each of circuits 100, 200, 400, and 500A-500C, each of arrays 600A and 600B is capable of realizing the benefits discussed above based on a combined heat transfer of at least two thermoelectric structures 602 coupled to a single energy source 614 or energy storage device 644.

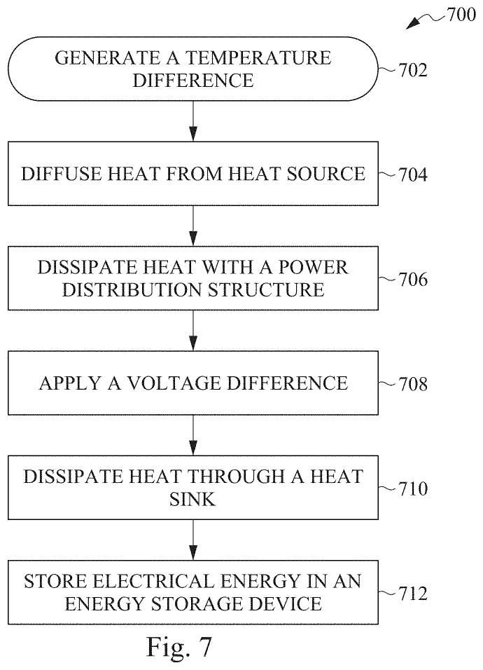

FIG. 7 is a flow diagram of a method 700 of cooling a circuit, in accordance with some embodiments. Method 700 is operable to transfer heat in one or more ICs, e.g., circuit 100, 200, 300, 400, and/or 500A-500C, and/or arrays 600A and/or 600B discussed above with respect to FIGS. 1-6B.

The sequence in which the operations of method 700 are depicted in FIG. 7 is for illustration only; the operations of method 700 are capable of being executed simultaneously and/or in sequences that differ from that depicted in FIG. 7. In some embodiments, operations in addition to those depicted in FIG. 7 are performed before, between, during, and/or after the operations depicted in FIG. 7.

At operation 702, in some embodiments, a temperature difference is created by generating heat with a heat source, e.g., a densely populated IC. Generating heat with a heat source includes generating heat with the heat source on a front side of a substrate. In some embodiments, generating the heat is based on Joule heating of a conductor from current propagating through a resistance of the conductor.

In some embodiments, creating the temperature difference by generating heat includes generating the heat with one or more heat sources 116 discussed above with respect to FIGS. 1-6B.

At operation 704, in some embodiments, heat is diffused from the heat source. Diffusing the heat from the heat source includes diffusing the heat from the front side of the substrate to a back side of the substrate. In some embodiments, diffusing the heat includes diffusing the heat to a thermoelectric structure electrically isolated from the heat source, e.g., thermoelectric structure 102, 202, 402, 502, or 602 discussed above with respect to FIGS. 1-6B. In some embodiments, diffusing the heat includes diffusing the heat to a thermal structure electrically isolated from the heat source, e.g., thermal structure 302 discussed above with respect to FIGS. 3 and 4.

In some embodiments, diffusing heat from the heat source includes diffusing the heat using charge carriers within a p-type region, e.g., p-type region 104 in which positive charge carriers travel from the front side to the back side, and/or diffusing the heat using charge carriers within an n-type region, e.g., n-type region 106 in which negative charge carriers travel from the front side to the back side, as discussed above with respect to FIGS. 1-6B.

In some embodiments, diffusing heat from the heat source includes using a wire to conduct a current between the n-type region and the p-type region, e.g., using wire 108 to conduct current 122 from n-type region 106 to p-type region 104, as discussed above with respect to FIGS. 1-6B.

In some embodiments, diffusing heat from the heat source includes directing the heat from the heat source with one or both of a p-type inactive region adjacent to the p-type region, e.g., PMOS dummy device 244 adjacent to p-type region 104, or an n-type inactive region adjacent to the n-type region, e.g., NMOS dummy device 246 adjacent to n-type region 106, as discussed above with respect to FIGS. 2-6B.

At operation 706, in some embodiments, the heat is dissipated with a power distribution structure on the back side of the substrate. Dissipating the heat with the power distribution structure includes dissipating the heat with the power distribution structure thermally coupled to the n-type region and the p-type region, e.g., through one or more vias or other conductive segments. In some embodiments, dissipating the heat with the power distribution structure includes dissipating the heat with the power distribution structure electrically coupled to the n-type region and the p-type region.

In some embodiments, dissipating the heat with the power distribution structure includes dissipating the heat with a first power structure electrically and thermally coupled to the p-type region and a second power structure electrically and thermally coupled to the n-type region. In some embodiments, dissipating the heat with the power distribution structure includes dissipating the heat with power structures 110 and 112 discussed above with respect to FIGS. 1-6B.

In some embodiments, dissipating the heat with the power distribution structure includes dissipating the heat with a single power structure electrically and thermally coupled to the n-type region and the p-type region. In some embodiments, dissipating the heat with the power distribution structure includes dissipating the heat with mesh structure 350 discussed above with respect to FIGS. 3 and 4.

In some embodiments, dissipating the heat with the power distribution structure includes coupling a current path between the first and second power structures. In some embodiments, dissipating the heat with the power distribution structure includes coupling an energy device between the first and second power structures, e.g., coupling energy device 114 discussed above with respect to FIGS. 1-6B.

At operation 708, in some embodiments, a voltage difference is applied to the first and second power structures. Applying the voltage difference to the first and second power structures includes applying the voltage difference to the thermoelectric structure, e.g., thermoelectric structure 102, 202, 402, 502, or 602 discussed above with respect to FIGS. 1-6B, thereby operating the thermoelectric structure as an active thermoelectric structure.

In various embodiments, applying the voltage difference to the first and second power structures includes applying the voltage from an energy source on or external to the substrate on which the first and second power structures are located. In some embodiments, applying the voltage difference to the first and second power structures includes applying voltage V1 from energy device 114 to power structures 110 and 112 discussed above with respect to FIGS. 1-4 or applying voltage V from energy source 614 discussed above with respect to FIGS. 6A and 6B.

In some embodiments, applying the voltage difference to the first and second power structures includes applying the voltage to an array of thermoelectric structures including first and second power structures, e.g., one of arrays 600A or 600B including instances of thermoelectric structure 602, discussed above with respect to FIGS. 6A and 6B.

At operation 710, in some embodiments, the heat is dissipated through a heat sink thermally coupled to the power distribution structure, e.g., heat sink 126 thermally coupled to power structures 110 and 112 and/or mesh structure 350, discussed above with respect to FIGS. 1-6B.

At operation 712, in some embodiments, electrical energy from the thermoelectric structure is stored in an energy storage device. Storing the electrical energy includes receiving the electrical energy from the thermoelectric structure, e.g., thermoelectric structure 102, 202, 402, 502, or 602 discussed above with respect to FIGS. 1-6B, thereby operating the thermoelectric structure as a passive thermoelectric structure.

Receiving the electrical energy from the thermoelectric structure includes receiving the electrical energy from the power distribution structure, e.g., from power structures 110 and 112 discussed above with respect to FIGS. 1-6B. Receiving the electrical energy from the thermoelectric structure includes receiving a current, e.g., current 122 discussed above with respect to FIGS. 1-6B.

In some embodiments, storing the electrical energy in the energy storage device includes storing the electrical energy in an energy storage device external to the substrate on which the thermoelectric structure are located, e.g., an energy storage embodiment of energy device 114 discussed above with respect to FIGS. 1-4, or energy storage device 644 discussed above with respect to FIGS. 6A and 6B.

In some embodiments, storing the electrical energy in the energy storage device includes storing the electrical energy in one or more energy storage devices on the substrate on which the thermoelectric structure is located, e.g., a capacitive device 514A or 514B discussed above with respect to FIGS. 5A-5C.

In some embodiments, storing the electrical energy from the thermoelectric structure in the energy storage device includes storing the electrical energy from an array of thermoelectric structures, e.g., storing the electrical energy from one of arrays 600A or 600B including instances of thermoelectric structure 602 in energy storage device 644, discussed above with respect to FIGS. 6A and 6B.

By executing some or all of the operations of method 700, an IC is cooled by transferring heat from a front side to a back side, e.g., by operating a thermoelectric structure as either an active or passive thermoelectric structure, thereby realizing the benefits discussed above with respect to circuits 100, 200, 300, 400, 500A-500C and arrays 600A and 600B.

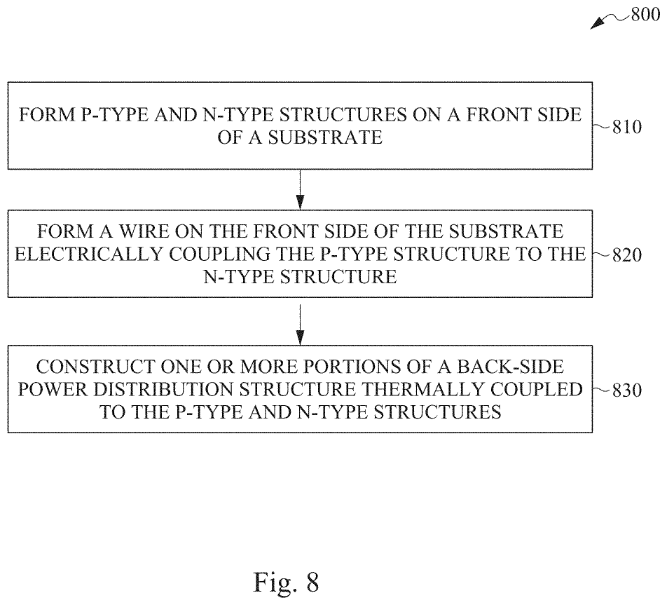

FIG. 8 is a flowchart of a method 800 of manufacturing an IC structure, in accordance with some embodiments. Method 800 is operable to form some or all of an IC, e.g., some or all of circuit 100, 200, 300, 400, and/or 500A-500C, and/or arrays 600A and/or 600B discussed above with respect to FIGS. 1-6B.

The sequence in which the operations of method 800 are depicted in FIG. 8 is for illustration only; the operations of method 800 are capable of being executed simultaneously and/or in sequences that differ from that depicted in FIG. 8. In some embodiments, operations in addition to those depicted in FIG. 8 are performed before, between, during, and/or after the operations depicted in FIG. 8.

In some embodiments, one or more operations of method 800 are executed using various fabrication tools, e.g., one or more of a wafer stepper, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed below.

At operation 810, p-type and n-type structures are formed on a front side of a substrate. Forming the p-type and n-type structures includes forming the p-type and n-type structures electrically isolated from one or more heat sources, e.g., heat sources 116 discussed above with respect to FIGS. 1-6B. In some embodiments, forming the p-type and n-type structures includes forming p-type region 104 and n-type region 106 on a front side of one of substrates 130-530C discussed above with respect to FIGS. 1-5C.

In some embodiments, forming the p-type and n-type structures includes forming one or both of one or more PMOS dummy devices adjacent to the p-type structure or one or more NMOS dummy devices adjacent to the n-type structure, e.g., forming one or more PMOS dummy devices 244 adjacent to p-type region 104 and one or more NMOS dummy devices 246 adjacent to n-type region 106, discussed above with respect to FIGS. 2-4.

In some embodiments, forming the p-type and n-type structures includes forming an array of p-type and n-type structures, e.g., p-type and n-type structures included in instances of thermoelectric structures 602 in array 600A or 600B, discussed above with respect to FIGS. 6A and 6B.

In various embodiments, forming the p-type and n-type structures includes forming one or more epitaxial layers or nano-sheets.

Forming structures and/or dummy devices includes using one or more suitable processes, e.g., photolithography, etch, and/or deposition processes. In some embodiments, the photolithography process includes forming and developing a photoresist layer to protect predetermined regions of the substrate while an etch process, e.g., a reactive ion etch, is used to form recesses in the substrate. In some embodiments, the deposition process includes performing an atomic layer deposition (ALD) in which one or more monolayers are deposited.

In some embodiments, forming the p-type and n-type structures includes forming one or more additional structures on the p-type and n-type structures, e.g., one or more silicide layers, conductive segments, via structures, gate structures, metal interconnect structures, or the like. In some embodiments, forming the p-type and n-type structures includes forming one or more of vias 103 or 105 discussed above with respect to FIGS. 1-6B.

At operation 820, in some embodiments, a wire is formed on the front side of the substrate electrically coupling the p-type structure to the n-type structure. In various embodiments, forming the wire includes forming the wire directly contacting each of the p-type and n-type structures, or one or neither of the p-type or n-type structures. In some embodiments, forming the wire includes forming wire 108 electrically coupling p-type region 104 to n-type region 106 discussed above with respect to FIGS. 1-4.

In some embodiments, forming the wire includes forming an array of wires, e.g., wires included in instances of thermoelectric structures 602 in array 600A or 600B, discussed above with respect to FIGS. 6A and 6B.

Forming the wire includes using one or more suitable processes, e.g., photolithography, etch, and/or deposition processes. In some embodiments, an etch process is used to form openings in the substrate, and a deposition process is used to fill the openings. In some embodiments, using the deposition process includes performing a chemical vapor deposition (CVD) in which one or more conductive materials are deposited.

In some embodiments, forming the wire includes forming one or more additional features, e.g., one or more conductive layers and/or via structures between the wire and one or both of the p-type or n-type structures.

In some embodiments, forming the wire on the front side of the substrate includes forming one or more additional features on the front side of the substrate, e.g., one or more front-side capacitive devices such as capacitive device 514A discussed above with respect to FIGS. 5A-5C.

At operation 830, one or more portions of a back-side power distribution structure thermally coupled to the p-type and n-type structures are constructed. In some embodiments, constructing the one or more portions of the back-side power distribution structure thermally coupled to the p-type and n-type structures includes constructing the one or more portions of the back-side power distribution structure electrically coupled to the p-type and n-type structures.

In some embodiments, constructing the one or more portions of the back-side power distribution structure includes constructing a first power structure thermally coupled to the p-type structure and a second power structure thermally coupled to the n-type structure. In some embodiments, constructing the one or more portions of the back-side power distribution structure includes constructing power structures 110 and 112 discussed above with respect to FIGS. 1-6B.

In some embodiments, constructing the one or more portions of the back-side power distribution structure includes constructing a single power structure thermally coupled to the p-type and n-type structures. In some embodiments, constructing the one or more portions of the back-side power distribution structure includes constructing mesh structure 350 discussed above with respect to FIGS. 3 and 4.

In some embodiments, constructing the one or more portions of the back-side power distribution structure includes forming an array of back-side power distribution structure portions, e.g., back-side power distribution structure portions included in instances of thermoelectric structures 602 in array 600A or 600B, discussed above with respect to FIGS. 6A and 6B.

Constructing the one or more portions of the back-side power distribution structure includes forming a plurality of conductive segments supported and electrically separated by one or more insulation layers. In some embodiments, forming the one or more insulation layers includes depositing one or more insulation materials, e.g., dielectric materials. In some embodiments, forming the conductive segments includes performing one or more deposition processes to deposit one or more conductive materials as discussed above with respect to FIGS. 1-6B.

In some embodiments, constructing the one or more portions of the back-side power distribution structure includes performing one or more manufacturing processes, e.g., one or more deposition, patterning, etching, planarization, and/or cleaning processes, suitable for creating conductive structures arranged in accordance with power distribution requirements.

In some embodiments, constructing the one or more portions of the back-side power distribution structure includes performing a thinning operation on the substrate prior to constructing the back-side power distribution structure, e.g., substrate 130-530C discussed above with respect to FIGS. 1-6B.

In some embodiments, constructing the one or more portions of the back-side power distribution structure includes forming one or more via or other conductive structures in the substrate and thermally coupled to the p-type and n-type structures prior to constructing the back-side power distribution structure. In some embodiments, constructing the one or more portions of the back-side power distribution structure includes forming vias 132 and 134 discussed above with respect to FIGS. 1-6B.

In some embodiments, constructing the one or more portions of the back-side power distribution structure includes forming one or more additional features on the back side of the substrate, e.g., one or more conductive segments and/or back-side capacitive devices such as conductive segments 510 and/or 530 and/or capacitive device 514B discussed above with respect to FIGS. 5A-5C.

In some embodiments, constructing the one or more portions of the back-side power distribution structure includes forming one or more vias and pads, e.g., vias 138 and 140 and pads 136 and 142 discussed above with respect to FIGS. 1-6B.

In some embodiments, constructing the one or more portions of the back-side power distribution structure includes bonding one or more energy devices to the one or more pads, e.g., bonding one or more of energy device 114, energy source 614, or energy storage device 644 discussed above with respect to FIGS. 1-6B.

In some embodiments, constructing the one or more portions of the back-side power distribution structure includes attaching one or more heat sinks, e.g., heat sink 126 discussed above with respect to FIGS. 1-6B.

In some embodiments, constructing the one or more portions of the back-side power distribution structure includes including the substrate in an IC package, e.g., a 3D or fanout package.

By executing some or all of the operations of method 800, some or all of an IC is formed including a corresponding one or more of thermoelectric and/or thermal structures 102, 202, 302, 402, 502 and/or 602 configured as an active or passive structure such that the IC is capable of realizing the benefits discussed above with respect to circuits 100, 200, 300, 400, and 500A-500C and arrays 600A and 600B.

In some embodiments, a method of manufacturing an IC structure includes forming active regions including doping areas of a substrate, forming source/drain regions including doping first areas of the active regions, forming conductive segments over corresponding ones of the source/drain regions, wherein the forming active regions, the forming source/drain regions, and the forming conductive segments results in a thermoelectric structure including a p-type region positioned on a front side of the substrate, an n-type region positioned on the front side of the substrate, and a wire on the front side of the substrate configured to electrically couple the p-type region to the n-type region. The method also includes forming a first via configured to thermally couple the p-type region to a first power structure on a back side of the substrate, forming a second via configured to thermally couple the n-type region to a second power structure on the back side of the substrate, and electrically coupling an energy device to each of the first and second power structures. In some embodiments, forming active regions, forming source/drain regions, and forming conductive segments further result in the p-type region and the n-type region being electrically isolated from one or more heat sources on the front side of the substrate. In some embodiments, forming active regions, forming source/drain regions, and forming conductive segments further result in a PMOS dummy device adjacent to the p-type region on the front side of the substrate. In some embodiments, forming active regions, forming source/drain regions, and forming conductive segments further result in a PMOS active device adjacent to and electrically isolated from the PMOS dummy device. In some embodiments, forming active regions, forming source/drain regions, and forming conductive segments further result in an NMOS dummy device adjacent to the n-type region on the front side of the substrate. In some embodiments, forming active regions, forming source/drain regions, and forming conductive segments further result in an NMOS active device adjacent to and electrically isolated from the NMOS dummy device. In some embodiments, forming active regions, forming source/drain regions, and forming conductive segments further result in an array of multiple p-type regions including the p-type region and multiple n-type regions including the n-type region on the front side of the substrate.

In some embodiments, a method of manufacturing an IC structure includes forming active regions in a substrate, forming S/D regions in the active regions, forming conductive segments over corresponding ones of the S/D regions, wherein forming active regions, S/D regions, and conductive segments result in a thermoelectric structure including a p-type S/D region positioned on a front side of the substrate, an n-type S/D region positioned on the front side of the substrate, and a wire on the front side of the substrate configured to electrically couple the p-type S/D region to the n-type S/D region. The method also includes forming first and second vias extending from the respective p-type and n-type S/D regions to a back side of the substrate, constructing first and second back-side power rails thermally coupled to the first and second vias, and electrically coupling an energy device to the first and second power rails. In some embodiments, the method includes performing a thinning operation on the substrate prior to constructing the first and second back-side power rails. In some embodiments, constructing first and second back-side power rails includes forming respective first and second back-side vias on the first and second back-side power rails and respective first and second pads on the first and second back-side vias, and electrically coupling the energy device to the first and second power rails includes bonding the energy device to the first and second pads. In some embodiments, the energy device includes an energy source configured to apply a voltage to the first and second power rails. In some embodiments, the energy device includes an energy storage device configured to receive a voltage from the first and second power rails. In some embodiments, the energy storage device includes a capacitive device on the front or back side of the substrate. In some embodiments, the method includes forming a heat sink on the back side of the substrate and thermally coupled to the first and second power rails. In some embodiments, the method includes forming a mesh structure located between the back side of the substrate and the heat sink, and between the first and second power rails.

In some embodiments, a method of manufacturing an IC structure includes forming active regions including doping areas of a substrate, forming S/D regions including doping first areas of the active regions, forming conductive segments over corresponding ones of the S/D regions, wherein the forming active regions, S/D regions, and conductive segments result in an array of thermoelectric structures positioned on the substrate, each thermoelectric structure including a p-type S/D region positioned on a front side of the substrate, an n-type S/D region positioned on the front side of the substrate; and a wire on the front side of the substrate configured to electrically couple the p-type region to the n-type region. The method also includes forming first vias configured to thermally couple each p-type S/D region to a corresponding first power structure on a back side of the substrate, forming second vias configured to thermally couple each n-type S/D region to a corresponding second power structure on the back side of the substrate, and electrically coupling an energy device to a first power structure of a first thermoelectric structure of the array of thermoelectric structures and to a second power structure of a second thermoelectric structure of the array of thermoelectric structures. In some embodiments, forming active regions, S/D regions, and conductive segments further result in the array of thermoelectric structures arranged as a plurality of rows of thermoelectric structures, and electrically coupling the energy device includes electrically coupling the energy device to each row of the plurality of rows of thermoelectric structures arranged in parallel. In some embodiments, forming active regions, S/D regions, and conductive segments further result in the array of thermoelectric structures arranged as a series of thermoelectric structures, and the electrically coupling the energy device includes electrically coupling the energy device to the first thermoelectric structure being the first thermoelectric structure of the series of thermoelectric structures and the second thermoelectric structure being a last thermoelectric structure of the series of thermoelectric structures. In some embodiments, the energy device includes an energy source configured to apply a voltage to the first and second thermoelectric structures. In some embodiments, the energy device includes an energy storage device configured to receive a voltage from the first and second thermoelectric structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an integrated circuit (IC) structure, the method comprising:
forming active regions including doping areas of a substrate;
forming source/drain regions including doping first areas of the active regions;
forming conductive segments over corresponding ones of the source/drain regions,
wherein the forming active regions, the forming source/drain regions, and the forming conductive segments result in a thermoelectric structure including:
a p-type region positioned on a front side of the substrate;
an n-type region positioned on the front side of the substrate; and
a wire on the front side of the substrate configured to electrically couple the p-type region to the n-type region;
forming a first via configured to thermally couple the p-type region to a first power structure on a back side of the substrate;
forming a second via configured to thermally couple the n-type region to a second power structure on the back side of the substrate; and
electrically coupling an energy device to each of the first and second power structures.

2. The method of claim 1, wherein the forming active regions, the forming source/drain regions, and the forming conductive segments further result in:
the p-type region and the n-type region being electrically isolated from one or more heat sources on the front side of the substrate.

3. The method of claim 1, wherein the forming active regions, the forming source/drain regions, and the forming conductive segments further result in:
a PMOS dummy device adjacent to the p-type region on the front side of the substrate.

4. The method of claim 3, wherein the forming active regions, the forming source/drain regions, and the forming conductive segments further result in:
a PMOS active device adjacent to and electrically isolated from the PMOS dummy device.

5. The method of claim 1, wherein the forming active regions, the forming source/drain regions, and the forming conductive segments further result in:
an NMOS dummy device adjacent to the n-type region on the front side of the substrate.

6. The method of claim 5, wherein the forming active regions, the forming source/drain regions, and the forming conductive segments further result in:
an NMOS active device adjacent to and electrically isolated from the NMOS dummy device.

7. The method of claim 1, wherein the forming active regions, the forming source/drain regions, and the forming conductive segments further result in:
an array of multiple p-type regions including the p-type region and multiple n-type regions including the n-type region on the front side of the substrate.

8. A method of manufacturing an integrated circuit (IC) structure, the method comprising:
forming active regions in a substrate;
forming source/drain (S/D) regions in the active regions;
forming conductive segments over corresponding ones of the S/D regions, wherein the forming active regions, S/D regions, and conductive segments result in a thermoelectric structure including:
a p-type S/D region positioned on a front side of the substrate;
an n-type S/D region positioned on the front side of the substrate; and
a wire on the front side of the substrate configured to electrically couple the p-type S/D region to the n-type S/D region;
forming first and second vias extending from the respective p-type and n-type S/D regions to a back side of the substrate;
constructing first and second back-side power rails thermally coupled to the first and second vias; and
electrically coupling an energy device to the first and second power rails.

9. The method of claim 8, further comprising:
performing a thinning operation on the substrate prior to constructing the first and second back-side power rails.

10. The method of claim 8, wherein:
the constructing first and second back-side power rails comprises forming respective first and second back-side vias on the first and second back-side power rails and respective first and second pads on the first and second back-side vias, and
the electrically coupling the energy device to the first and second power rails comprises bonding the energy device to the first and second pads.

11. The method of claim 8, wherein:
the energy device comprises an energy source configured to apply a voltage to the first and second power rails.

12. The method of claim 8, wherein:
the energy device comprises an energy storage device configured to receive a voltage from the first and second power rails.

13. The method of claim 12, wherein:
the energy storage device comprises a capacitive device on the front or back side of the substrate.

14. The method of claim 8, further comprising:
forming a heat sink on the back side of the substrate and thermally coupled to the first and second power rails.

15. The method of claim 14, further comprising:
forming a mesh structure located between the back side of the substrate and the heat sink, and between the first and second power rails.

16. A method of manufacturing an integrated circuit (IC) structure, the method comprising:
forming active regions including doping areas of a substrate;
forming source/drain (S/D) regions including doping first areas of the active regions;
forming conductive segments over corresponding ones of the S/D regions,
wherein the forming active regions, S/D regions, and conductive segments result in an array of thermoelectric structures positioned on the substrate, each thermoelectric structure including:
a p-type S/D region positioned on a front side of the substrate;
an n-type S/D region positioned on the front side of the substrate; and
a wire on the front side of the substrate configured to electrically couple the p-type region to the n-type region;
forming first vias configured to thermally couple each p-type S/D region to a corresponding first power structure on a back side of the substrate;
forming second vias configured to thermally couple each n-type S/D region to a corresponding second power structure on the back side of the substrate; and
electrically coupling an energy device to a first power structure of a first thermoelectric structure of the array of thermoelectric structures and to a second power structure of a second thermoelectric structure of the array of thermoelectric structures.

17. The method of claim 16, wherein:
the forming active regions, S/D regions, and conductive segments further result in the array of thermoelectric structures arranged as a plurality of rows of thermoelectric structures, and
the electrically coupling the energy device comprises electrically coupling the energy device to each row of the plurality of rows of thermoelectric structures arranged in parallel.

18. The method of claim 16, wherein:
the forming active regions, S/D regions, and conductive segments further result in the array of thermoelectric structures arranged as a series of thermoelectric structures, and
the electrically coupling the energy device comprises electrically coupling the energy device to the first thermoelectric structure being the first thermoelectric structure of the series of thermoelectric structures and the second thermoelectric structure being a last thermoelectric structure of the series of thermoelectric structures.

19. The method of claim 16, wherein:
the energy device comprises an energy source configured to apply a voltage to the first and second thermoelectric structures.

20. The method of claim 16, wherein:
the energy device comprises an energy storage device configured to receive a voltage from the first and second thermoelectric structures.
